(19) United States
(12) Patent Application Publication
(10) Pub. No.: US 2024/0114645 A1
(43) Pub. Date: Apr. 4, 2024

(54) MODULAR AND SCALABLE POWER DISTRIBUTION

(71) Applicant: Panduit Corp., Tinley Park, IL (US)

(72) Inventors: Ronald A. Nordin, Naperville, IL (US); Masud Bolouri-Saransar, Orland Park, IL (US); Surendra Chitti Babu, Naperville, IL (US); Francis C. Cheo, Arlington Heights, IL (US); Daniel E. Host, Orland Park, IL (US); Michael D. Asztalos, Orland Park, IL (US); Eric Beaupre, Palos Park, IL (US)

(73) Assignee: Panduit Corp., Tinley Park, IL (US)

(21) Appl. No.: 18/538,534

(22) Filed: Dec. 13, 2023

Related U.S. Application Data
(63) Continuation-in-part of application No. 17/898,976, filed on Aug. 30, 2022.
Application No. 17/898,976 is a continuation-in-part of application No. 17/465,097, filed on Sep. 2, 2021.
(60) Provisional application No. 63/076,430, filed on Sep. 10, 2020.
(60) Provisional application No. 63/301,521, filed on Jan. 21, 2022.
(60) Provisional application No. 63/315,184, filed on Mar. 1, 2022.
(60) Provisional application No. 63/345,138, filed on May 24, 2022.

(51) Int. Cl. H05K 7/14; H01R 9/18; H01R 13/04; H01R 13/11; H01R 13/436; H01R 13/631; H01R 25/00; H02H 3/08

(52) U.S. Cl. CPC H05K 7/1492; H01R 9/18; H01R 13/04; H01R 13/113; H01R 13/4362; H01R 13/6315; H01R 25/006; H02H 3/083; H01R 2201/06

(57) ABSTRACT

A modular power distribution system includes using power extension modules and power distribution modules. The power extension modules are configured to route inputted power to another power extension module or a power distribution module. The power distribution modules are configured to route power from a power extension module to one or more racks or cabinets in a data center.

### CROSS REFERENCE TO RELATED APPLICATION(S)

This application is a continuation-in-part of U.S. patent application Ser. No. 17/898,976, filed Aug. 30, 2022, which is a continuation-in-part of U.S. patent application Ser. No. 17/465,097, filed Sep. 2, 2021, which claims the benefit of U.S. Provisional Patent Application Ser. No. 63/076,430, filed Sep. 10, 2020; U.S. Provisional Patent Application Ser. No. 63/301,521, filed Jan. 21, 2022; U.S. Provisional Patent Application Ser. No. 63/315,184, filed Mar. 1, 2022; and U.S. Provisional Patent Application Ser. No. 63/345,138, filed May 24, 2022, the entirety of which is hereby incorporated by reference herein.

### FIELD OF THE INVENTION

The present invention relates generally to power distribution systems and more specifically a modular power distribution system that combines the best features of a power bus system and a point-to-point wiring system.

### BACKGROUND

The power from the electric utility must be distributed efficiently to IT equipment contained within cabinets in data centers (or in enterprise or industrial settings). This power is typically distributed in 3-phase delta or wye configurations to each of the cabinets. The power is then connected to the cabinet's rack-PDU (power distribution unit) where the power is distributed to each of the IT equipment. Today's methods of distributing this power are designed specifically for the particular application.

As shown in FIG. 1, power first enters a facility from the electric utility at a high voltage level (typically 35 kV), where it is first stepped down to a low voltage (e.g., 480 VAC) and routed to a main switch gear. Here a selection between the utility power or a backup generator is selected. After the switch gear, the power is typically stepped down again to either 415 or 208 prior to or within the distribution cabinets. The distribution cabinets than route power to each of the PDU's where it is further distributed to the cabinets containing IT equipment.

Once the power is routed to the data hall's PDU, traditionally it has been distributed to the cabinets containing IT equipment by either point to point wiring or through a power bus method (see FIGS. 2A and 2B below). FIG. 2A shows a block diagram of a power bus method of distributing power to each cabinet's rack-based PDU. Power bus systems are typically routed above the cabinets only. The rack-based PDU(s) connects to a “tap-off-point” box that is connected to the power bus. These tap-off-points are required to contain a breaker and optionally can have a power measurement capability. Some of the drawbacks of a power bus system is the material cost of the equipment, the installation cost, and the consultative services required to design the power distribution system.

FIG. 2B shows a block diagram of a point-to-point wiring power distribution system. Power cables run from each of the rack-based PDUs to either a power distribution cabinet or a remote power panel. The point-to-point wiring can be either overhead or under floor (as shown). Some of the drawbacks of a point-to-point wiring method of power distribution include initial installation cost and the cost of making changes to the system.

### SUMMARY

A modular power distribution system includes using power extension modules and power distribution modules. The power extension modules are configured to route inputted power to another power extension module or a power distribution module. The power distribution modules are configured to route power from a power extension module to one or more racks or cabinets in a data center. In one embodiment, the modular power distribution system can also include power feed modules and/or breaker modules.

### BRIEF DESCRIPTION OF THE FIGURES

FIG. 1 shows a block diagram on how power is distributed in a data center.

FIG. 2A shows how power is distributed to cabinets using a power bus system.

FIG. 2B shows how power is distributed to cabinets using point-to-point wiring.

FIG. 3A shows a first embodiment of a modular power distribution system according to the present invention.

FIG. 3B shows the power distribution panel for the system of FIG. 3A.

FIG. 3C shows the power distribution and power extension modules for the system of FIG. 3A.

FIG. 4A further shows the power distribution module wiring.

FIG. 4B further shows the power extension module wiring.

FIG. 5A shows the breaker module.

FIG. 5B shows the power feed module.

FIG. 6A shows the overall system for a second embodiment of a modular power distribution system according to the present invention.

FIG. 6B shows the components of the system of FIG. 6A.

FIG. 7 is a chart showing the contact arrangement for the various modules.

FIG. 8 shows isometric views of the male and female contact housings.

FIG. 9 shows the UL 857 Finger Probe.

FIG. 10 is a cross-sectional view showing staggered contacts in the female housing.

FIG. 11 is a cross sectional view showing the engagement of the contacts between the male and female housings.

FIG. 12 is a cross sectional view showing with a chart showing the creepage and clearance distances from UL 587.

FIG. 13A is an isometric view of two modules being electrically connected via the connectors of FIG. 8.

FIG. 13B is a focused isometric view of the two modules in FIG. 13A.

FIG. 13C is another isometric view of the two modules in FIG. 13A.

FIG. 14 shows the components in a mechanical coupling mechanism to connect two modules.

FIG. 15 is an exploded view of the coupling mechanism of FIG. 14.

FIG. 16 shows an embodiment of a coupling mechanism similar to the one of FIG. 14 but with alignment/support bars.

FIG. 17A shows the first step in a sequence of steps in securing the coupling mechanism of FIG. 14.

FIG. 17B shows the second step in a sequence of steps in securing the coupling mechanism of FIG. 14.

FIG. 17C shows the third step in a sequence of steps in securing the coupling mechanism of FIG. 14.

FIG. 18 shows two modules coupled together through the coupling mechanism of FIG. 14.

FIG. 19 shows an isometric view of a first configuration of an exemplary embodiment of the modular power distribution system of FIG. 6A with brackets that can be used to mount it.

FIG. 20 is an exploded view of the modular power system and brackets of FIG. 19.

FIG. 21 is another isometric view of the system of FIG. 19.

FIG. 22 is an exploded isometric view of the system of FIG. 19.

FIG. 23 is an isometric view of the connection system showing a module being connected into the power feed module of FIG. 19.

FIG. 24 is an isometric view of the connection system showing a module being connected into the power feed module of FIG. 19.

FIG. 25 shows an isometric view of a second configuration of an exemplary embodiment of the modular power distribution system of FIG. 6A with brackets that can be used to mount it.

FIG. 26A shows an outer bracket of a bracket system that can be used with the present invention.

FIG. 26B shows a first inner bracket assembly.

FIG. 26C shows a second inner bracket assembly.

FIG. 26D shows a third inner bracket assembly.

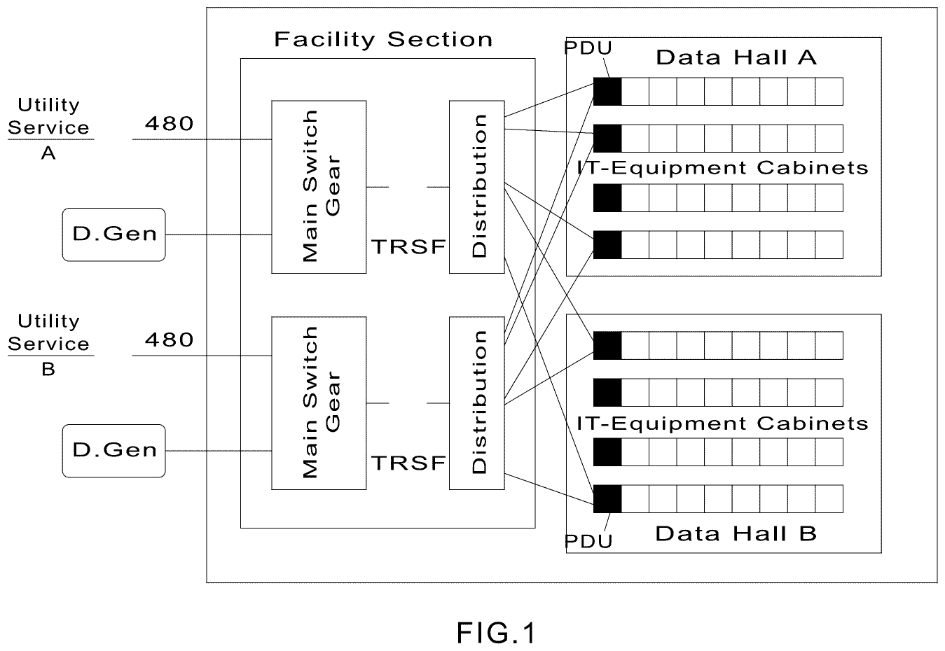

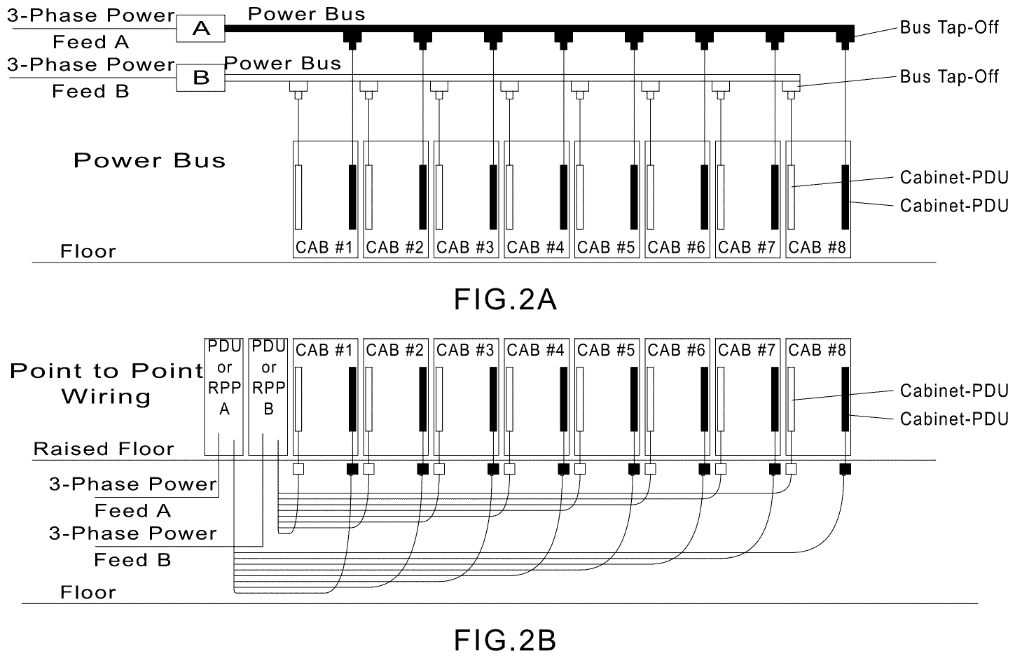

### DETAILED DESCRIPTION OF THE INVENTION

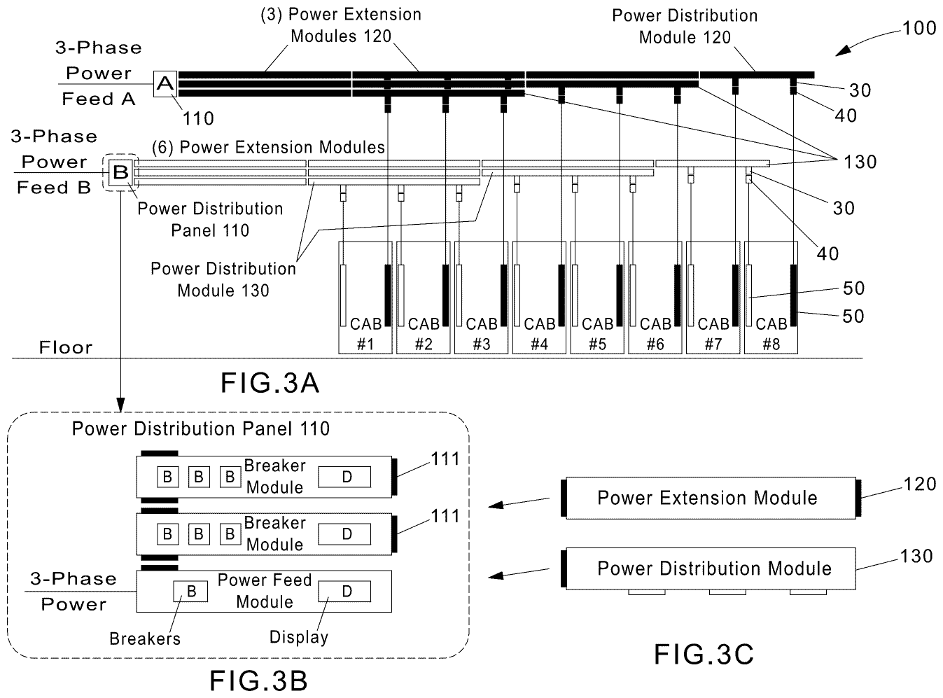

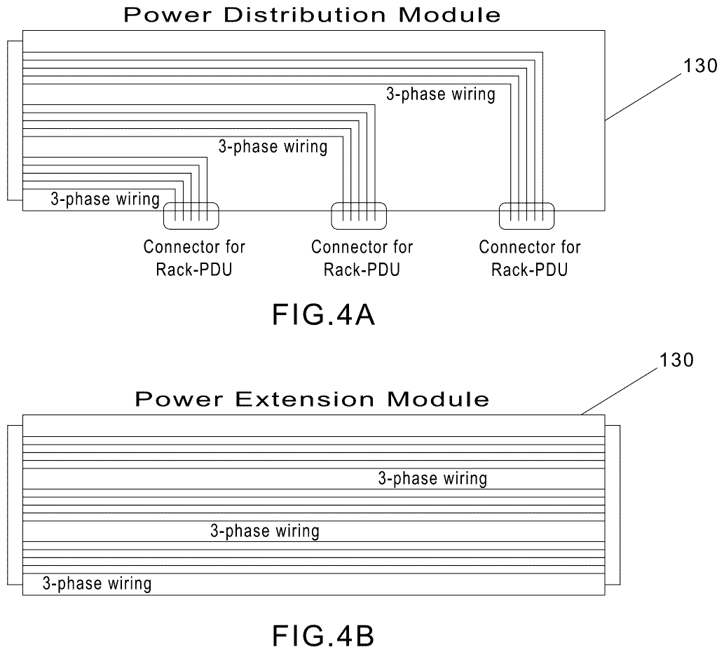

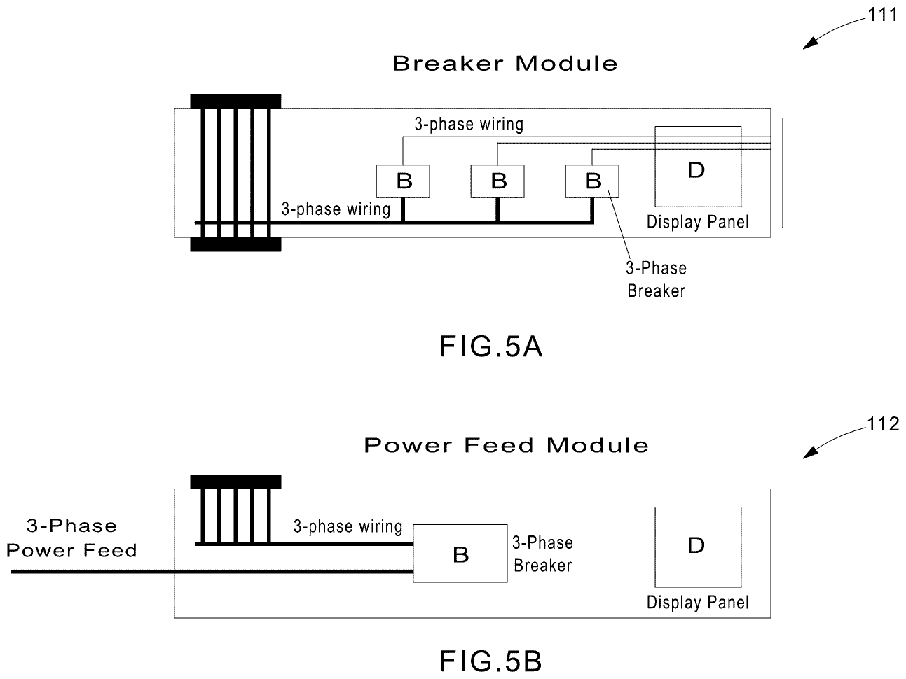

A first embodiment of a novel technique of distributing power is shown in FIG. 3A. This technique combines the best features of the power bus method and the best features of point-to-point wiring method. This technique offers a modular and scalable solution for the distribution of power. Each of the rack-based PDUs 50 plug into a power distribution module 130. The power distribution module 130 is equipped with outlets 30 where a multiple of rack-PDUs 50 can plug into (a preferred number is three or four). Additionally, the power distribution module 130 can contain branch circuit power monitoring circuitry. The power extension modules 120 do not have any outlets and its primary purpose is to serve as interface between the breaker module 111 of the power distribution panel 110 and power distribution module 130. (Additionally, the power extension modules 120 can transport the branch circuit monitoring information form the power distribution modules back to the power feed panel). The power distribution module connects to as many of the power extension modules as necessary to transfer power from the power distribution panel back to the power distribution panel (see FIG. 3A). These power distribution and extension modules are connectorized at the ends to plug into one another as well as plugging into the breaker module within the power distribution panel (see FIG. 3C and further shown in FIGS. 4A and 4B). The power distribution panel 110 is shown in FIG. 3B and further shown in FIGS. 5A and 5B. It is a modular and scalable system composing of two modules: the power feed module 112 and the breaker module 111. The power feed module 110 connects to the main power feed cable (typically a 3-phase delta or wye configuration) and to the breaker modules. The power feed module can contain a high-power breaker for the main power feed (and optionally a display panel to indicate the power levels being drawn from the main power feed). The breaker modules 111 can tap into the power from the power feed module and connect to other breaker modules 111 and either the power distribution or extension modules. The breaker module 111 contains a current breaker 60 for each of the power lines connecting to the rack-based PDUs 50 (three 3-phase breakers are shown in FIG. 3C) and an optional display panel to indicate the power levels in each rack-PDU that it is connected to. Note the function of the breaker module 111 can be integrated into the power distribution modules 130 and the power extension modules 120.

The advantages of this power distribution method are:
Lower part cost and simpler design;
A lower cost of installation;
Ease of installation and ease of scalability to larger systems; and
No consultative services required for the system design.

The technique provides the flexibility, scalability, and modularity of a power bus system at the cost of a point-to-point system.

FIGS. 4A and 4B describe the wiring for both the power distribution 130 and extension modules 120. FIG. 4A shows the wiring diagram for the power distribution module 130 which connects the end connector to each of the PDU connectors. FIG. 4B shows the wiring diagram for the power extension module 120 which connects the two end connectors together.

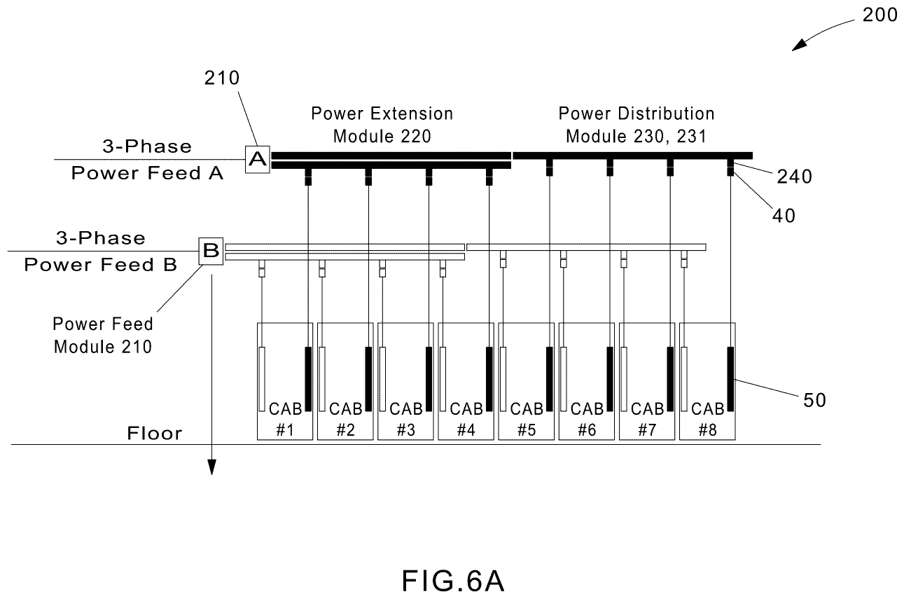

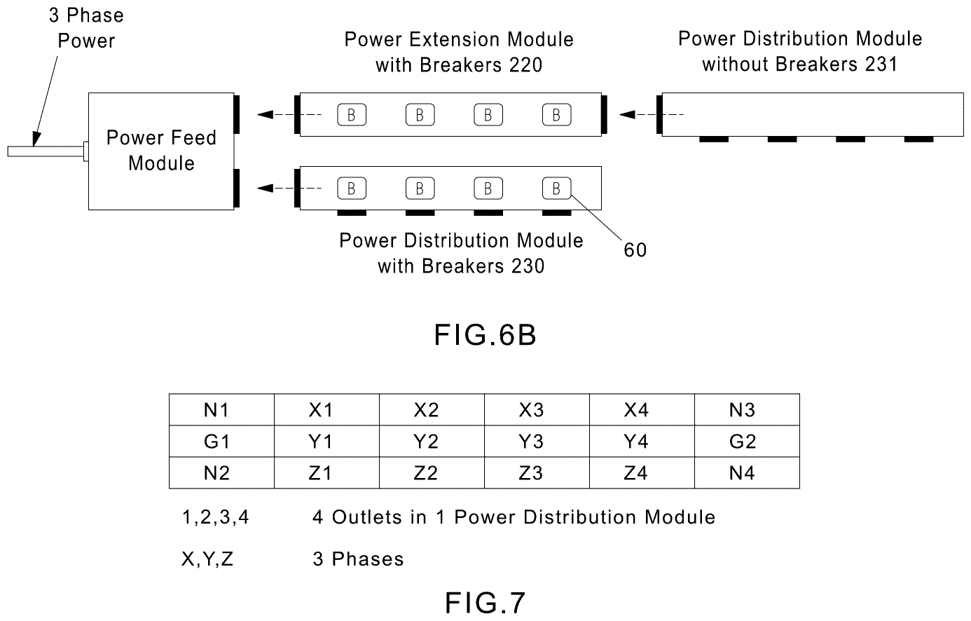

A second embodiment which uses modular outlets in the power distribution module is shown in FIGS. 6A and 6B and described.
1. Power Feed Module 210 (PFM): PFM 210 is designed to work with various 3-phase power configurations from building such as 208V Delta, 208V Wye or 415V Wye. The main power feed cable is fed into the PFM 210 and power is distributed within to the end connectors and eventually to the connected power extension module 220 (PEM) and power distribution module 230, 231 (PDM). Depending on the number of cabinets that need power, the PFM 210 can be scaled. In this example, 8 cabinets are powered by the system; hence two rows of PEM/PDM combination is shown.
2. Power Extension Module 220 (PEM) and Power Distribution Module 230, 231 (PDM): In this embodiment shown with 8 cabinets (FIGS. 6A and 6B), power distribution module 230 is equipped with 4 circuit breakers 60 and 4 outlet housings 240 where rack-PDUs 50 can plug into (# of outlet housings/circuit breakers can be increased or decreased in other embodiments according to the number cabinets being powered by one PDM). Since the outlet housings 250 are modular, different outlet housings can be used depending on the equipment that is being powered. Power extension module 220 is equipped with 4 circuit breakers in this embodiment and could have more or fewer depending on the cabinets being powered by PDM. Subsequent PDM 231 connected to PEM 220 will not have circuit breakers 60.

As mentioned for PFM 210, for a layout with a number of cabinets higher than 8, PFM 210 can be scaled up along with increasing the # of PEMs and PDMs. For a 4-cabinet layout, PEM 220 will not be used.

PEMs and PDMs are not restricted to any particular cabinet widths. Different length of PEMs and PDMs can be made to match the cabinet widths as well as “spacer” PEMs to accommodate in-row deployments such as vertical managers, in-row coolers, etc. that do not require an electrical outlet.

In different embodiments, this design can be adapted to provide power to non-IT equipment that are outside cabinets as well; for example, by using a different outlet housings.

Connectorizing these different modules such as Power Feed Module 210, Power Extension Module 220 and Power Distribution Module 230, 231 is one of the key aspects of this design. In order to achieve this, power connector with multiple contact terminals will be used to make the necessary electrical connections between different modules.

In one implementation of such a design, each PDM 230,231 provides power to 4 cabinets thereby requiring 18 contact terminals as shown in FIG. 7 (4 contacts each for Phase X, Y, Z, Neutral and 2 shared grounds). As a result, the connector housing was developed to house all 18 contacts. In this embodiment, a commonly available type of contact terminals are used. Plastic housings could be designed appropriately for different type of terminal contacts. Within the power connector, a multitude of contact terminals and thereby their corresponding phases, neutral and ground are laid in a specific manner such that symmetry is accomplished. As a result, the power connector does not require a certain orientation and greatly aids during the assembly process and minimizes error.

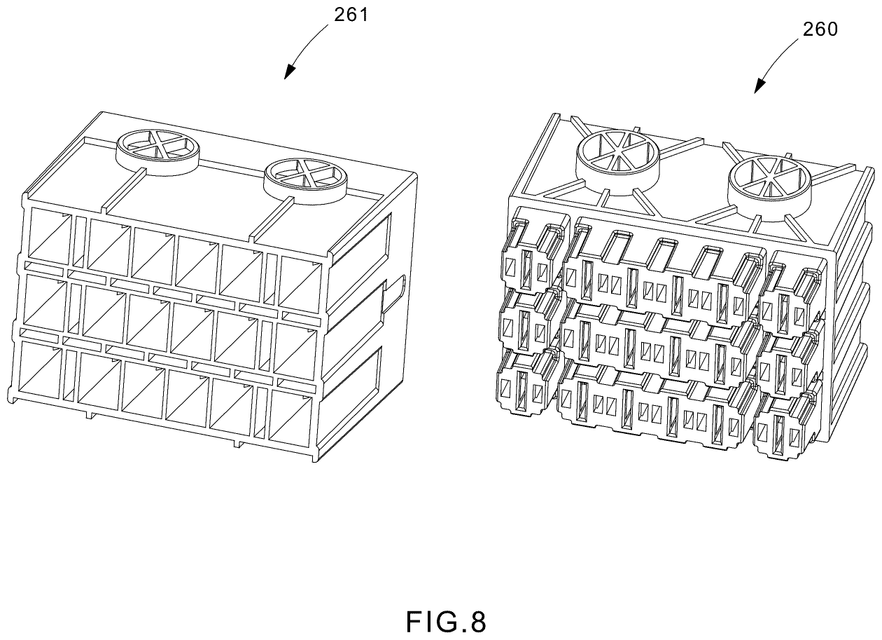

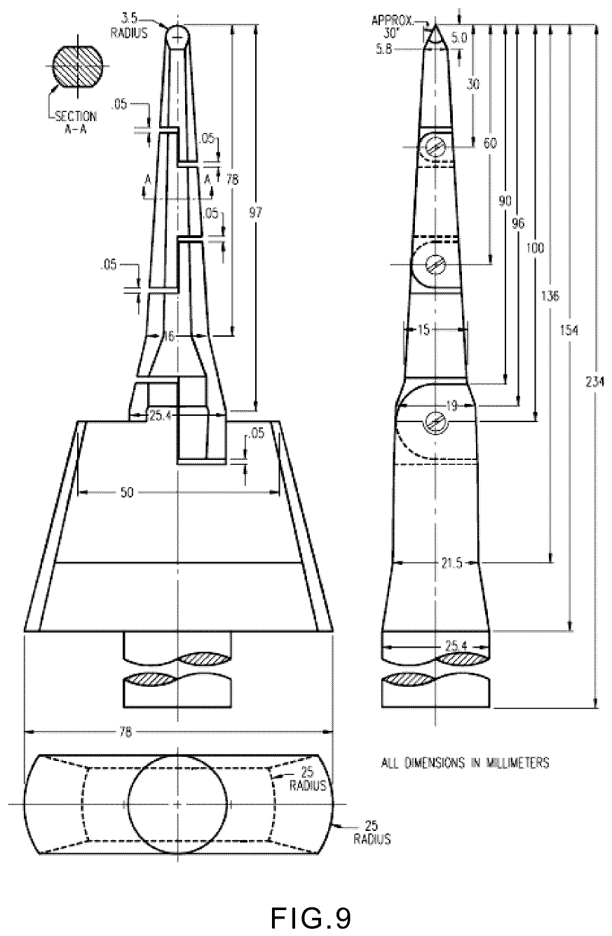

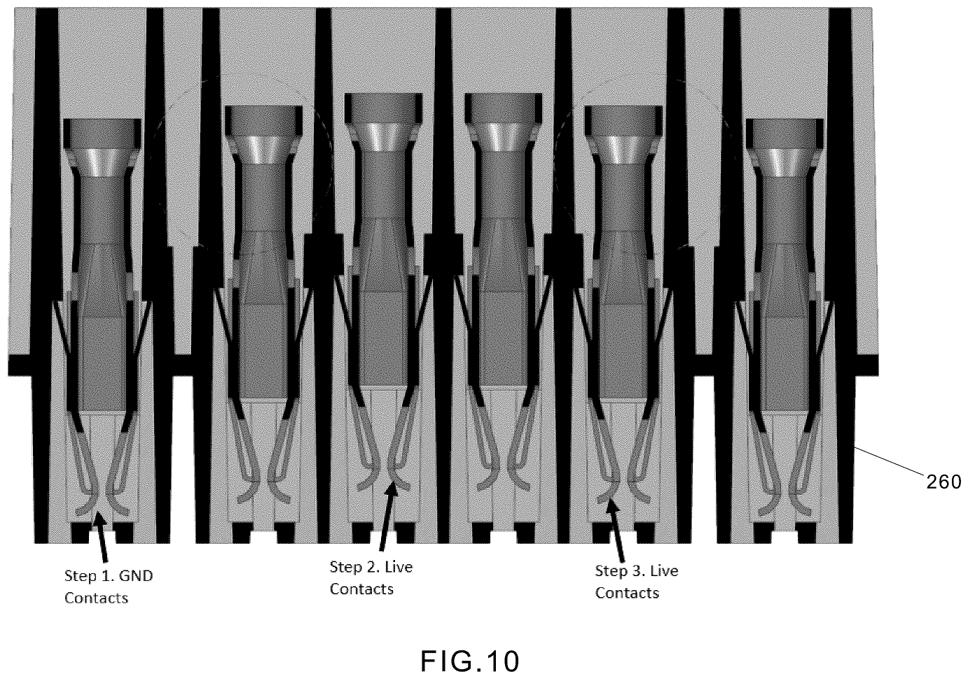

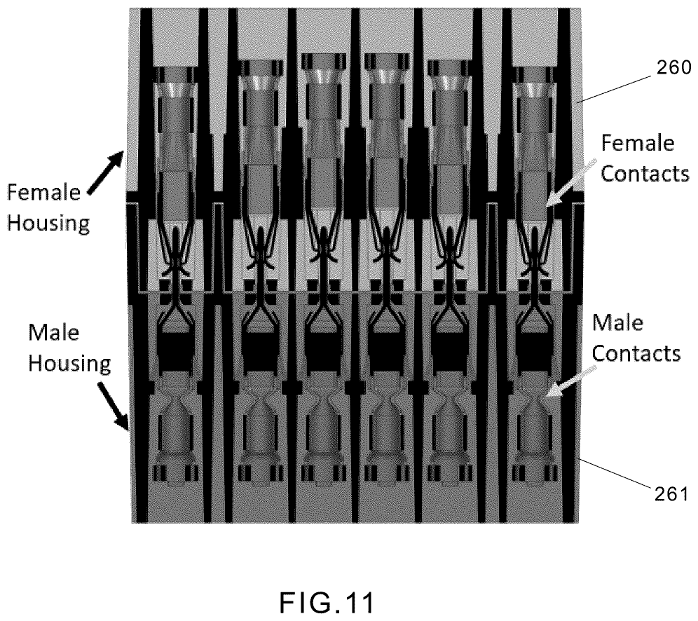

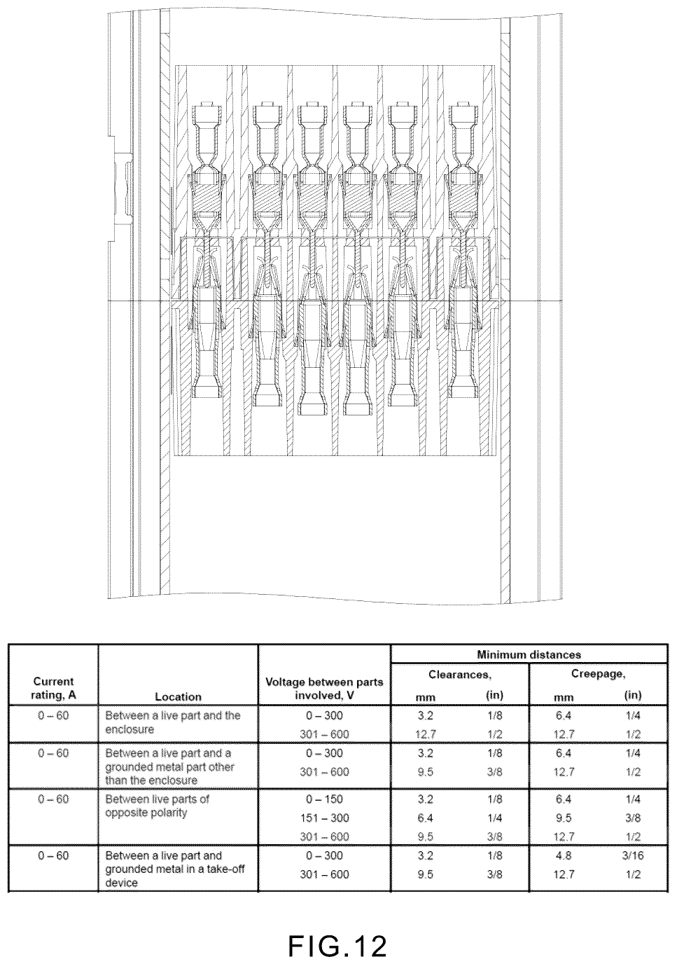

The connector housings shown in FIG. 8 (male housing 261, female housing 260) are designed to ensure the following:
1. Finger-safety: The opening in the female housing 260 (as shown in FIG. 8) and placement of the receptable contacts within the housing is designed such that it is compliant to Section 7.4.6 in UL 857 (FIG. 9). The male contacts are not energized until they have engaged with the female power connector.
2. Ground contact safety: Ground receptacle contacts in the female housing 260 (FIG. 10) are positioned ahead of live contacts such that ground contacts are the first to engage and last to disconnect.
3. Reduction in the connector insertion force: Individual contacts have considerable insertion force (˜10 lbs) thereby reducing the contact resistance. In order to reduce the amount of insertion force during installation, contacts are staggered (FIG. 11) in three stages such that only few contacts are inserted at a time rather than all contacts in one stage. This arrangement creates different timing in response to the peak force of each stage. In this current embodiment, a total of 18 contacts would have required approximately 180 lbs. and by designing three stages of insertion, required insertion force is reduced at each stage.
4. Creepage and clearance distances are maintained: Connector housing is designed to meet the required creepage and clearance as required by UL857 as shown in FIG. 12.

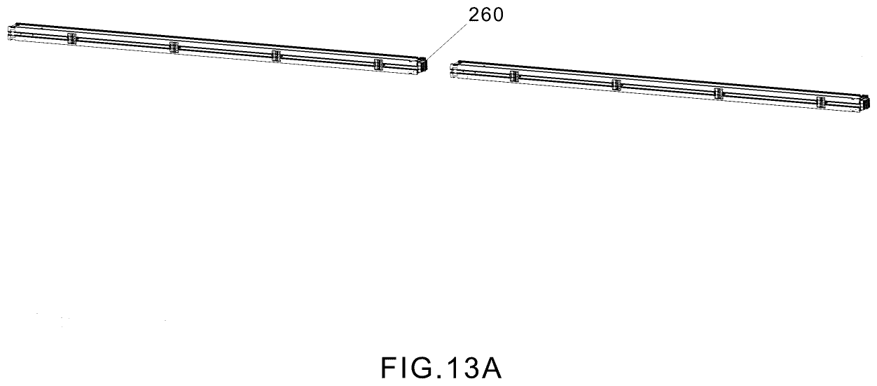

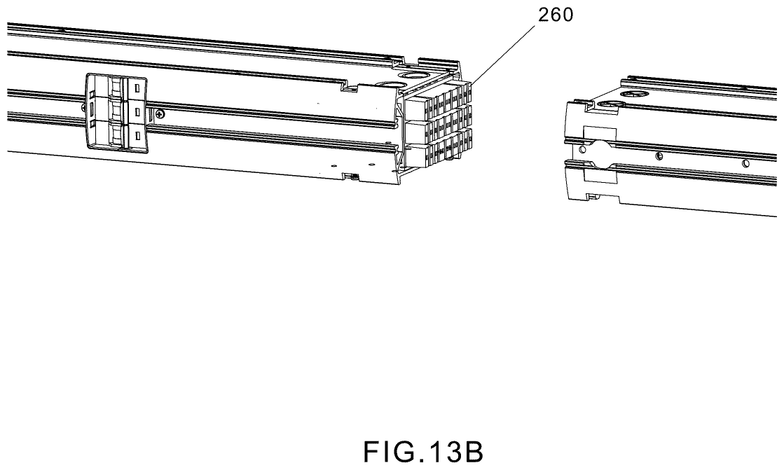

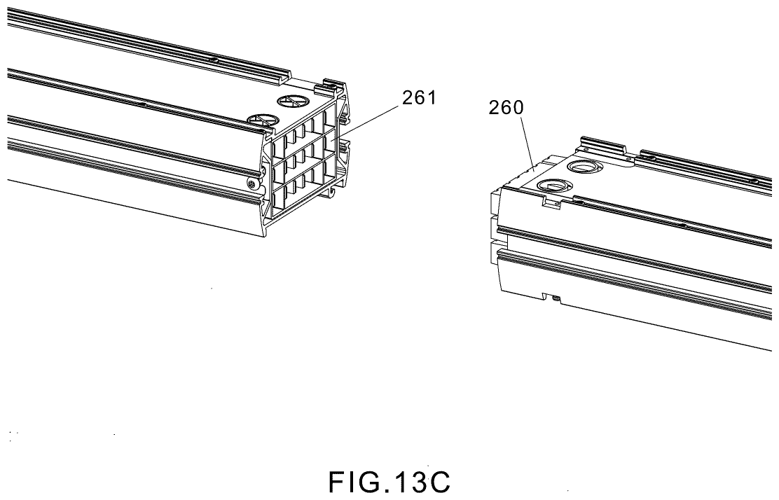

A new mechanism 300 is developed as detailed in this document that enables insertion and removal of one module into another easier. This mechanism can be used with any regular tool such as nut driver, ratchet or it could be also used with aid of a power tool. The end of power distribution modules, power extension modules and power feed modules are connectorized using the power connectors. An example of the power modules with power connectors which would be engaged is shown in FIGS. 13A-C.

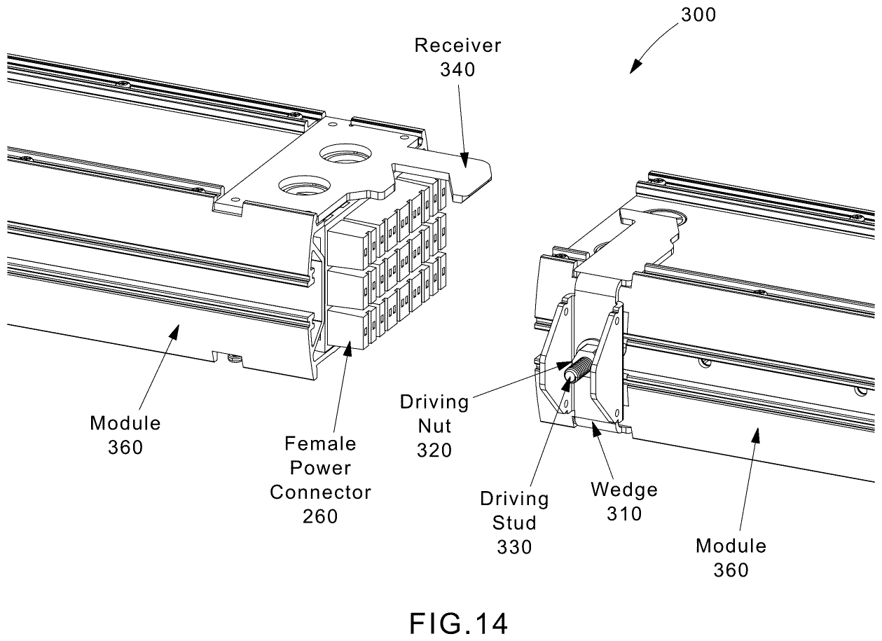

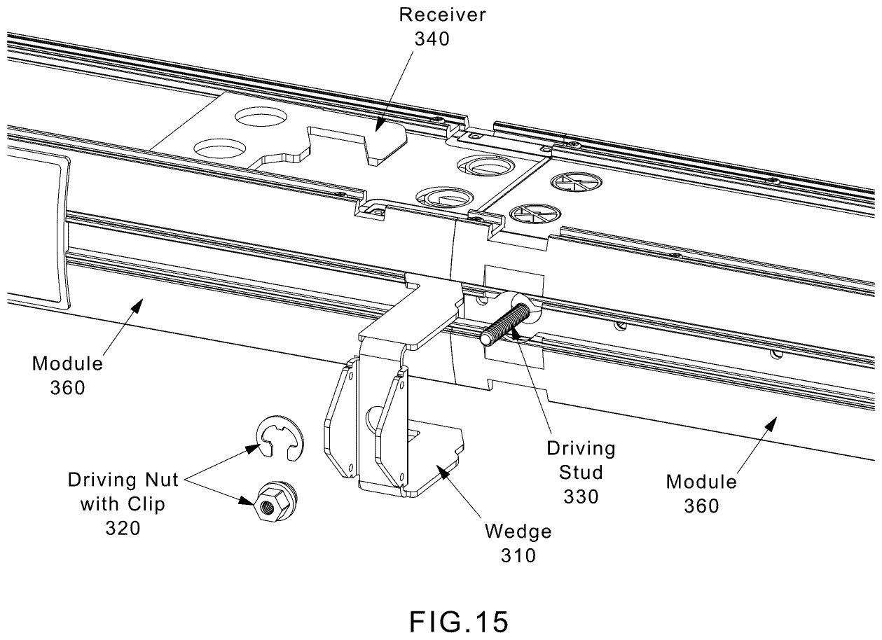

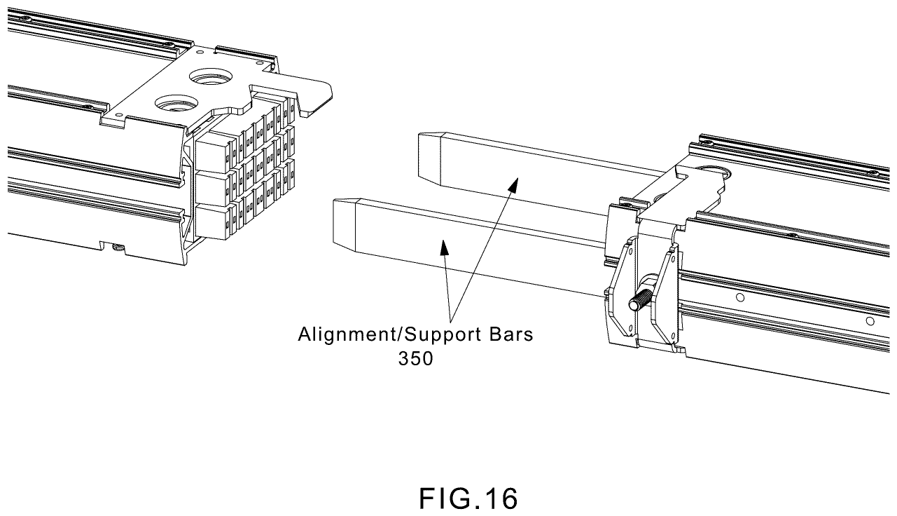

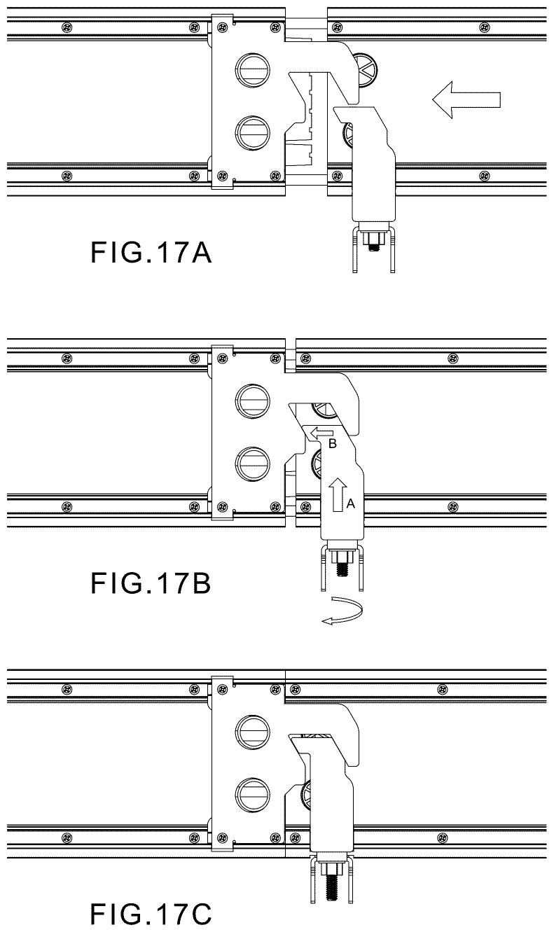

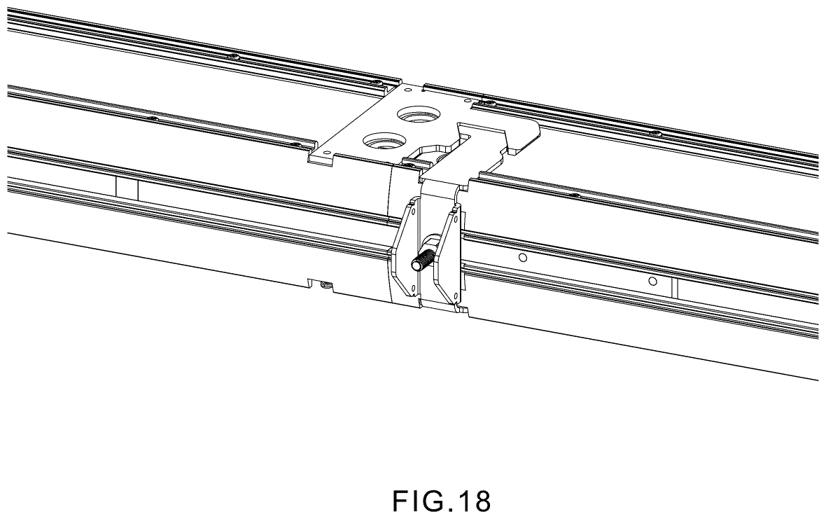

The main parts of the mechanism 300 are wedge 310, driving nut 320 and stud 330 (part of the inserting module), and receiver 340 (part of receiving module) as shown in FIG. 14 and FIG. 15. An alignment/support bar 350 (FIG. 16) would be used to aid the insertion process. As follows:
Step 1: Modules 360 are first aligned with each other.
Step 2: Driving nut 320 is rotated using a simple tool such as nut driver or ratchet. As the nut is driven, the wedge moves in the Y direction, engages the receiver 340 and slides in the X direction, thereby moving and inserting one power module into the other.
Step 3: At end of the travel, both the 360 modules and all the contact terminals will be fully engaged and locked in place as shown in FIGS. 6A and 6B.

To separate the two modules 360, steps 1, 2, and 3 are done in reverse order. There is a certain amount of insertion force requirement when mating the male/female terminals to create the connection. Insertion force for a single terminal could be approximately ˜10 lbs. With multitude of terminals within the power connector being used (18 terminals in this embodiment) to power numerous IT equipment, connecting male and female connectors would require significant amount of force. A coupling mechanism was designed that would provide a mechanical advantage to the installer such that modules with multiple terminals are connected with simple tools (ex: nut driver) without any special tooling.

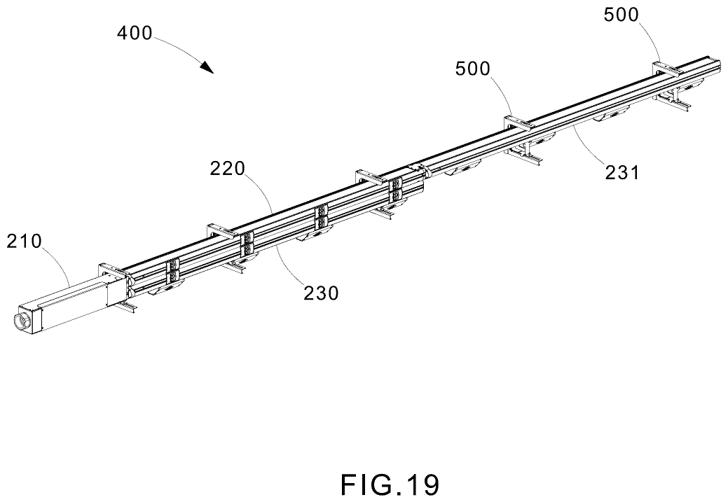

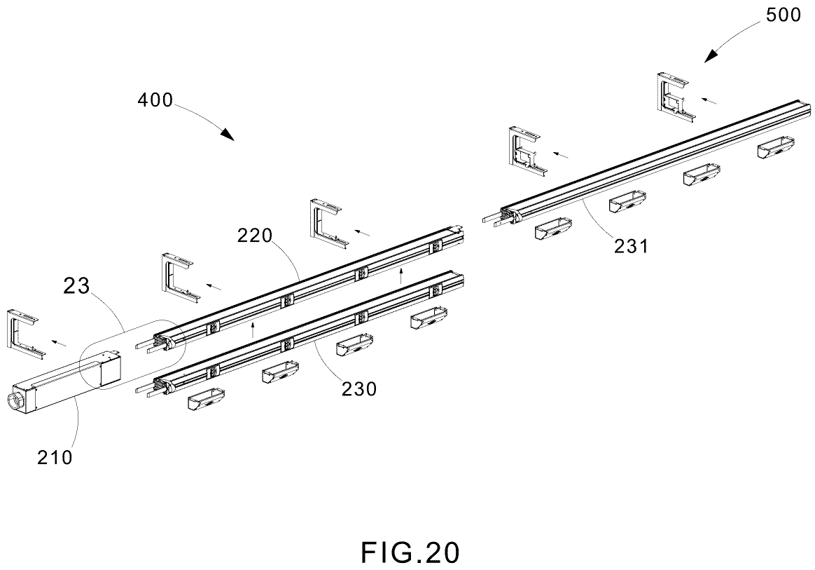

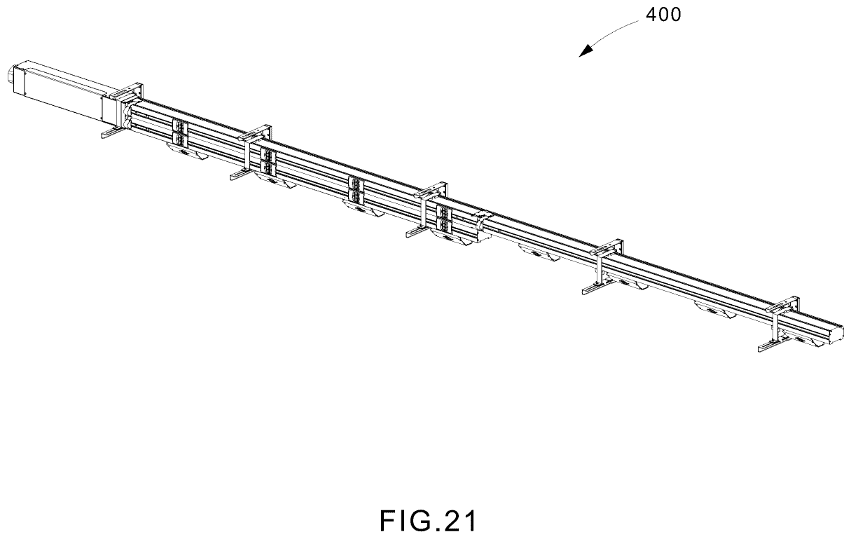

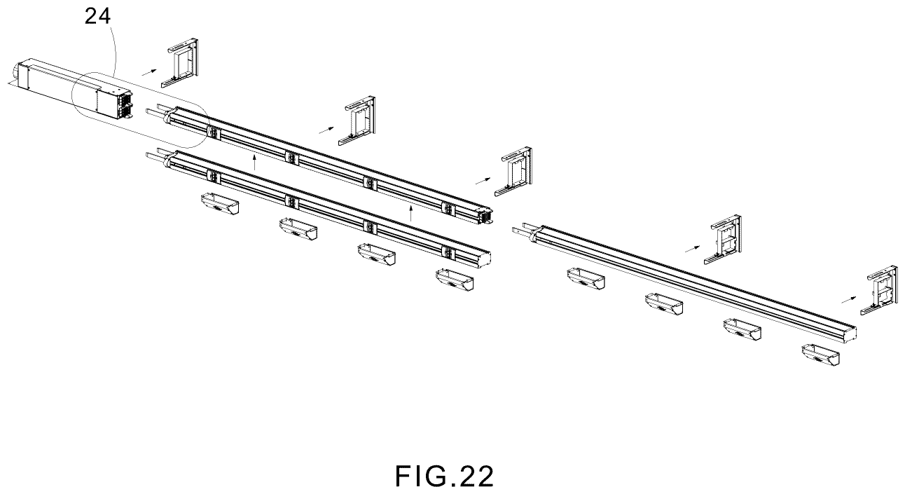

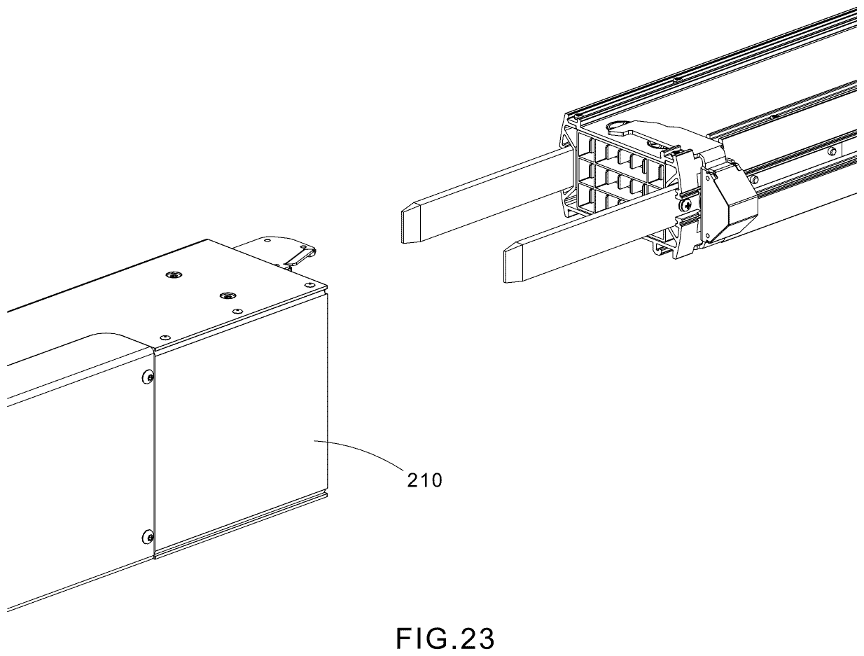

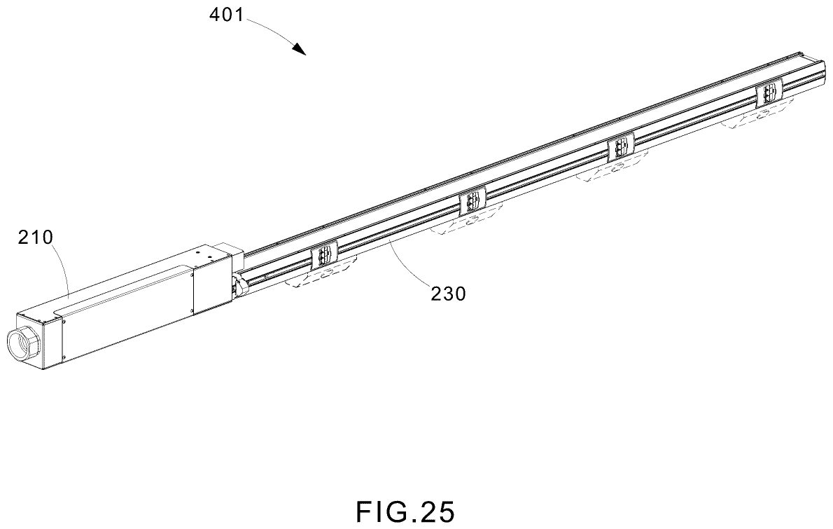

FIGS. 19-26 show an exemplary embodiment of the present invention which uses two specific configurations 400, 401. The first configuration 400 is shown in FIGS. 19-22 uses a power feed module 210, a power extension module 220, a power distribution module with breakers 230 and a power distribution module without breakers 231. In the embodiment shown, the first exemplary configuration can be utilized for up to 8 server cabinets (due to having 8 outlets housings 250). The second configuration 401, shown in FIG. 25, uses a power feed module 210, and a power distribution module with breakers 230. This embodiment, shown in FIG. 25, can be utilized to provide power up to four cabinets. One in skill of the art would be able to adjust the number of outlets housings 250 in the power distribution modules 230, 231 in order to change the number of outlets and provide power to a different number of cabinets.

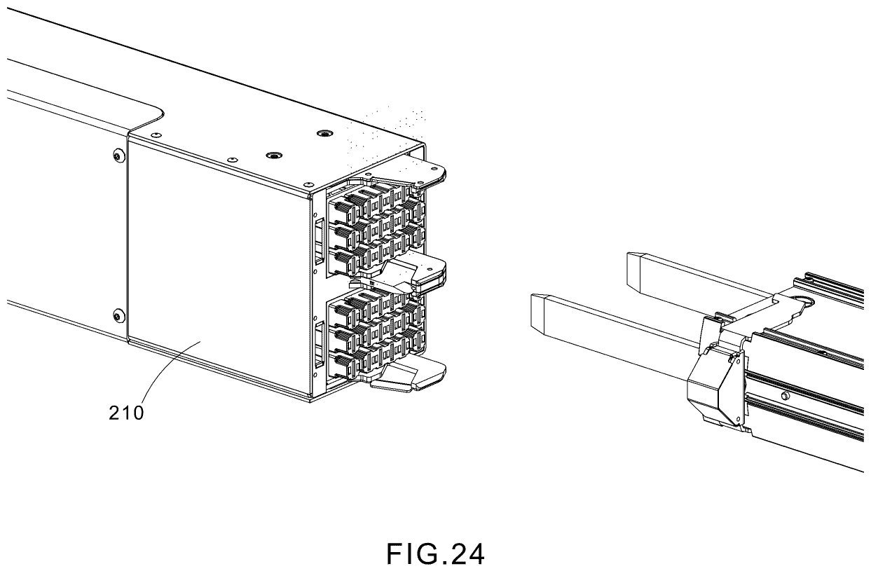

FIGS. 24 and 25 show how the use of top and bottom connectors can be used to attach two modules to a power feed module.

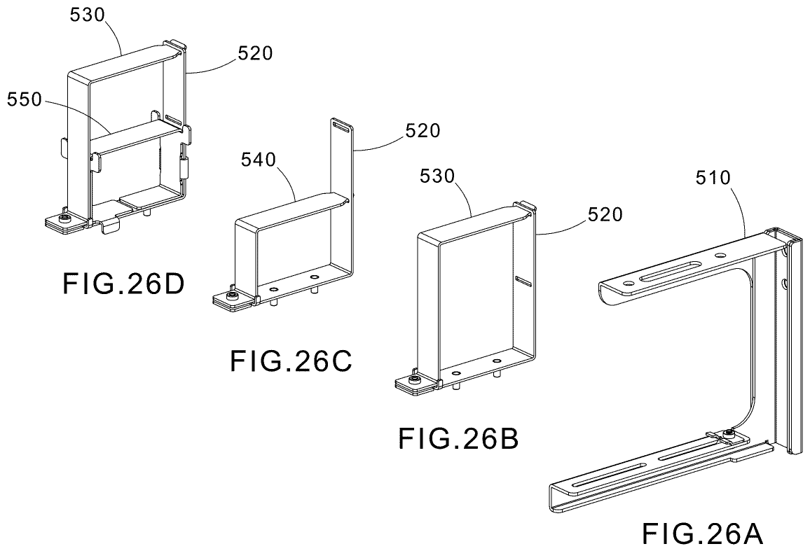

FIGS. 26A-D show the bracket system 500 that can be used with the present invention which allows the modular system to be mounted over the server cabinets. The bracket system can have an outer bracket 510 with an innerbracket assembly that consists of an inner back bracket 520 which can be combined with tall inner front bracket 530 (to be used for the power feed module or two modules stacked on top of each other), a short inner front bracket 540 (to be used for just a lower module such as in FIG. 25), or an inner top module support 550 (which is combined with the inner tall front bracket 530 to support a top module as in FIG. 19). In order to mount a system, the outer brackets are mounted above the server cabinets, the inner back brackets are secured to the outer brackets (if only mounting a top module, the inner top module support 550 bracket will be installed as well) The modules will then be placed on the brackets and then secured by adding either an inner tall front bracket 530 or an inner short front bracket 540 as needed.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

1. A modular system for the distribution of power comprising:
a power feed module; and
a power distribution module wherein the system allows for a first configuration and a second configuration, the first configuration has a first number of outlet housings, the second configuration has a second number of outlet housings, and the first number of outlet housings being approximately double the second number of outlet housings.

2. The modular system of claim 1 wherein the first configuration also includes a power extension module and a second power distribution module.

3. The modular system of claim 2 wherein the first number of outlet housings is 4.

4. The modular system of claim 2 wherein the power extension module has breakers, the second power distribution module has breakers, the first power distribution module does not have breakers, and the first power distribution module is connected to the power feed module via the power extension module.

5. The modular system of claim 2 wherein the modules are connected to each other via connectors wherein the contacts in the connectors are staggered to reduce insertion force.

6. The modular system of claim 5 wherein the contacts are staggered such that ground contacts are the first to engage and the last to disconnect.

7. The modular system of claim 1 further comprising a bracket system, the bracket system includes an outer bracket and an inner brackets assembly.

8. The modular system of claim 7 wherein the inner bracket assembly includes one of an inner rear bracket and a tall inner front bracket, an inner rear bracket and a short inner front bracket, or an inner rear bracket, inner top module support and a tall inner front bracket.
